(19) United States
(12) Patent Application Publication
(10) Pub. No.: US 2018/0158828 A1
(43) Pub. Date: Jun. 7, 2018

(54) SEMICONDUCTOR DEVICE INCLUDING MULTI-LINER LAYER IN TRENCH

(71) Applicant: Samsung Electronics Co., Ltd., Suwon-si (KR)

(72) Inventors: Seung-uk HAN, Suwon-si (KR); Soo-jin HONG, Guri-si (KR); Wook-yeol YI, Hwaseong-si (KR)

(73) Assignee: Samsung Electronics Co., Ltd., Suwon-si (KR)

(21) Appl. No.: 15/673,843

(22) Filed: Aug. 10, 2017

(30) Foreign Application Priority Data
Dec. 1, 2016 (KR) 10-2016-0162922

(51) Int. Cl. H01L 27/108; H01L 29/06; H01L 21/02; H01L 29/423; H01L 49/02; H01L 21/768; H01L 21/762

(52) U.S. Cl. CPC H01L 27/10823; H01L 21/31116; H01L 21/02164; H01L 21/0217; H01L 21/02233; H01L 21/0214; H01L 29/0684; H01L 29/4236; H01L 27/10814; H01L 28/90; H01L 27/10897; H01L 21/76804; H01L 21/76877; H01L 27/10885; H01L 27/10888; H01L 21/76224; H01L 21/02255; H01L 29/0649

(57) ABSTRACT

A semiconductor device may include a semiconductor substrate, a trench isolation layer on the semiconductor substrate and configured to define an active region, and a multi-liner layer on an inside wall of a trench including the trench isolation layer. The multi-liner layer may include a first liner layer on the inside wall of the trench, a second liner layer on the first liner layer, and a third liner layer on the second liner layer.

### CROSS-REFERENCE TO RELATED APPLICATION

This application claims the benefit of priority from Korean Patent Application No. 10-2016-0162922, filed on Dec. 1, 2016, in the Korean Intellectual Property Office, the disclosure of which is incorporated herein in its entirety by reference.

### BACKGROUND

The inventive concepts relate to a semiconductor device, and/or to a semiconductor device including a multi-liner layer in a trench.

It may be difficult for a transistor to operate stably due to high density integration of the semiconductor device. The transistor included in the semiconductor device may include an active region defined by a trench isolation layer. When the trench isolation layer is clearly, physically or electrically, separate from the active region, the transistor may stably operate.

### SUMMARY

The inventive concepts provide a semiconductor device including a multi-liner layer in a trench for a clear physical or electrical separation of an active region from a trench isolation layer.

According to some example embodiments, there is provided a semiconductor device including: a semiconductor substrate; a trench isolation layer on the semiconductor substrate and configured to define an active region; and a multi-liner layer on an inside wall of a trench including the trench isolation layer, wherein the multi-liner layer includes a first liner layer on the inside wall of the trench, a second liner layer on the first liner layer, and a third liner layer on the second liner layer.

According to some example embodiments, there is provided a semiconductor device including: a semiconductor substrate including a cell region and a peripheral circuit region; a trench isolation layer on the semiconductor substrate including the cell region and the peripheral circuit region, the trench isolation layer configured to define an active region; a multi-liner layer on an inside wall of a trench including the trench isolation layer in the cell region and the peripheral circuit region; a cell transistor in the cell region; and a peripheral circuit transistor in the peripheral circuit region, wherein the multi-liner layer in at least any one of the cell region and the peripheral circuit region includes a first liner layer on the inside wall of the trench, a second liner layer on the first liner layer, and a third liner layer on the second liner layer.

According to some example embodiments, there is provided a semiconductor device including: a semiconductor substrate; a trench isolation layer on the semiconductor substrate and configured to define an active region; and a multi-liner layer on an inside wall of a trench including the trench isolation layer, wherein the multi-liner layer includes a first liner layer on the inside wall of the trench and a second liner layer on the first liner layer. Some example embodiments relate to a semiconductor device including a semiconductor substrate, a trench in the semiconductor substrate, and a multi-liner layer on at least one inside wall of the trench, the multi-liner layer being configured to minimize a flow of charges therethrough.

### BRIEF DESCRIPTION OF THE DRAWINGS

Embodiments of the inventive concepts will be more clearly understood from the following detailed description cut in conjunction with the accompanying drawings in which:

FIG. 1 is a layout diagram of a semiconductor device according to an example embodiment of the inventive concepts;

FIG. 2 is a cross-sectional view of the semiconductor device cut along the line Y1-Y1′ in FIG. 1;

FIG. 3 is a cross-sectional view of the semiconductor device cut along the line X1-X1′ in FIG. 1;

FIG. 4 is a plan view of a semiconductor device according to an example embodiment of the inventive concepts;

FIG. 5 is a combination of cross-sectional views of a semiconductor device, respectively cut along lines A-A′ and B-B′ in FIG. 4, according to an example embodiment of the inventive concepts;

FIG. 6 is a combination of cross-sectional views of a semiconductor device, respectively cut along lines C-C′ and E-E′ in FIG. 4, according to an example embodiment of the inventive concepts;

FIG. 7 is a cross-sectional view of a semiconductor device cut along the line D-D′ in FIG. 4, according to an example embodiment of the inventive concepts;

FIG. 8 is an enlarged cross-sectional view of a portion F in FIG. 7;

FIGS. 9 through 13 are combinations of cross-sectional views of a semiconductor device, cut along the lines A-A′, B-B′, and C-C′ in FIG. 1, for illustrating a manufacturing method thereof, according to an example embodiment of the inventive concepts; and

FIG. 14 is a block diagram of an example of a memory system including a semiconductor device, according to an example embodiment of the inventive concepts;

FIG. 15 is a block diagram of an example of a memory card including a semiconductor device, according to an example embodiment of the inventive concepts; and

FIG. 16 is a block diagram of an example of an information processing system including a semiconductor device, according to an example embodiment of the inventive concepts.

### DETAILED DESCRIPTION

These and other features and advantages are described in, or are apparent from, the following detailed description of various example embodiments.

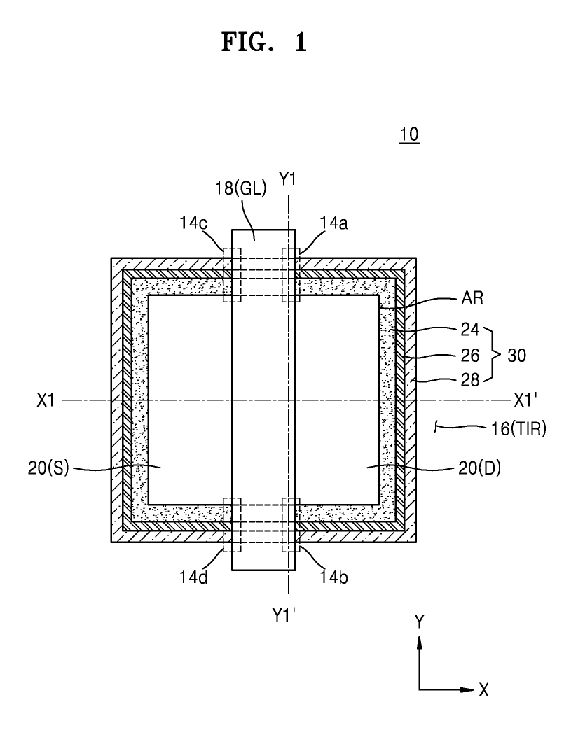

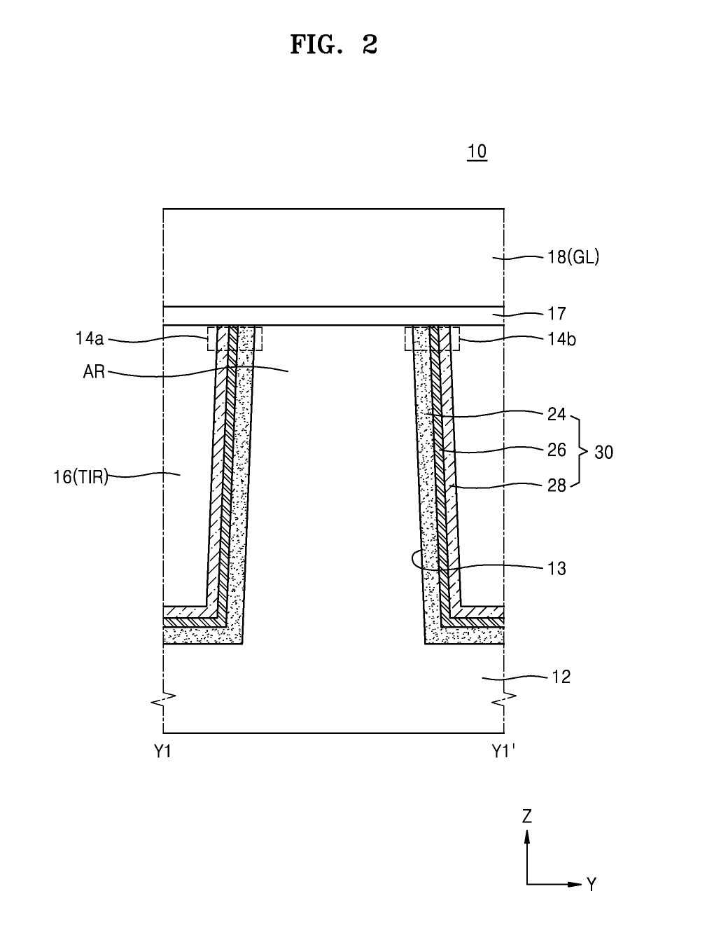

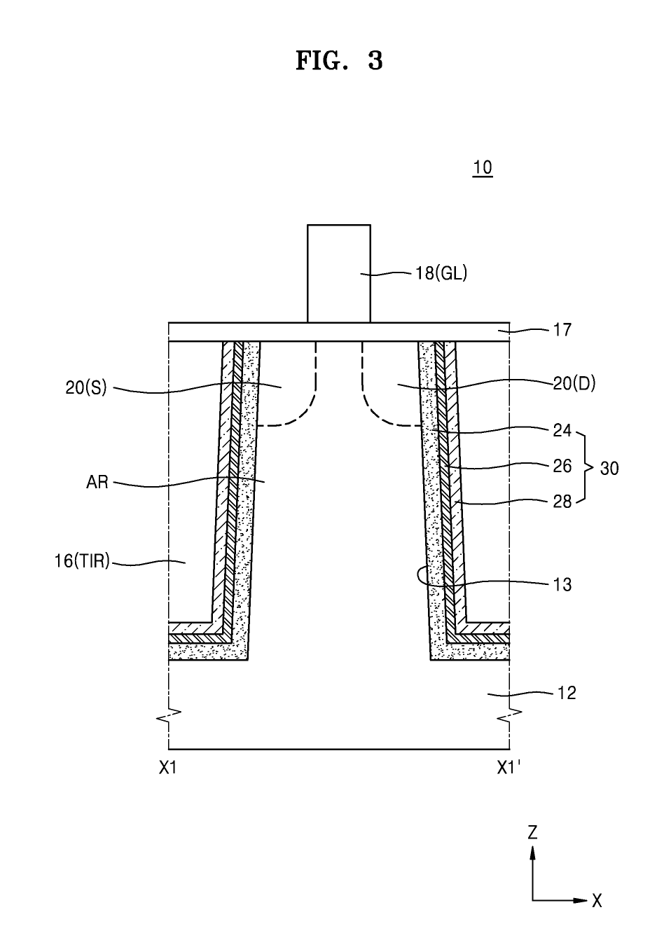

FIG. 1 is a layout diagram of a semiconductor device 10 according to an example embodiment of the inventive concepts, FIG. 2 is a cross-sectional view of the semiconductor device 10, cut along the line Y1-Y1′ in FIG. 1 and FIG. 3 is a cross-sectional view of the semiconductor device cut along the line X1-X1′ in FIG. 1.

The semiconductor device 10 may include a transistor, for example, a metal oxide semiconductor (MOS) transistor. The semiconductor device 10 may include an active region AR, a trench isolation layer 16, and a multi-liner layer 30 on a semiconductor substrate 12.

The semiconductor substrate 12 may be a substrate including at least one of silicon (Si) and germanium (Ge). For example, the semiconductor substrate 12 may be a Si substrate. The trench isolation layer 16 may be a trench isolation region (TIR). The TIR may be a shallow trench isolation (STI) region.

The active region AR may be defined by the trench isolation layer 16 on the semiconductor substrate 12. The trench isolation layer 16 may include an insulating layer buried inside a trench 13 which is formed via etching the semiconductor substrate 12. The trench isolation layer 16 may include at least one of silicon oxide, silicon nitride, and silicon oxynitride. According to an example embodiment, the trench isolation layer 16 may include silicon oxide. The AR may be a part of the semiconductor substrate 12.

The multi-liner layer 30 may be arranged on an inside wall of the trench 13. The multi-liner layer 30 may be arranged on a side wall and a bottom of the trench 13. The multi-liner layer 30 may include a first liner layer 24 on the inside wall of the trench 13, a second liner layer 26 on the first liner layer 24, and a third finer layer 28 on the second liner layer 26. In an example embodiment, the multi-liner layer 30 may include a first liner layer 24 on the inside wall of the trench 13 and a second liner layer 26 on the first liner layer 24. In FIGS. 1 through 3, the multi-liner layer 30 including a first liner layer 24, a second liner layer 26, and a third liner layer 28 is shown for convenience.

A charge trap density of the second liner layer 26 may be higher than the charge trap density of the first liner layer 24 and may be lower than the charge trap density of the third liner layer 28. In an example embodiment, a charge trap density of the second liner layer 26 may be higher than the charge trap density of the first liner layer 24. The second liner layer 26 may be a charge trap layer in which charge, for example, electrons may be trapped during operation of the semiconductor device 10.

According to an example embodiment, a thickness of the second liner layer 26 may be less than the thicknesses of the first and second liner layers 24 and 28. According to an example embodiment, the thickness of the second liner layer 26 may be less than the thickness of the first liner layer 24, but greater than the thickness of the third liner layer 28.

According to an example embodiment, the first liner layer 24 may include a silicon oxide layer (SiₓO_{y}, where x and y are positive integers), the second liner layer 26 may include a silicon oxynitride layer (SiOₓN_{y}, where x and y are positive integers), and the third liner layer 28 may include a silicon nitride layer (SiₓN_{y}, where x and y are positive integers). According to an example embodiment, the first liner layer 24 may include a silicon oxide layer (SiₓO_{y}, where x and y are positive integers), and the second liner layer 26 may include a silicon oxynitride layer (SiOₓN_{y}, here x and y are positive integers).

According to an example embodiment, the first liner layer 24 may be the silicon oxide layer formed via a thermal oxidation method, and the second liner layer 26 and the third liner layer 28 may respectively be the silicon oxynitride layer (SiOₓN_{y}, where x and y are positive integers) and the silicon nitride layer (SiₓN_{y}, where x and y are positive integers), which may be formed via, for example, a deposition method. The deposition method may be a chemical vapor deposition (CVD) method, an atomic layer deposition (ALD) method or other method.

The semiconductor device 10 may include a gate electrode 18 which crosses the active region AR in a first direction (a Y direction) and extends to the trench isolation layer 16 on the semiconductor substrate 12. The gate electrode 18 may include at least one of a doped semiconductor, a conductive metal nitride (for example, titanium nitride (TiN), tantalum nitride (TaN), or tungsten nitride (WN)), and a metal (for example, ruthenium (Ru), iridium (Ir), tungsten (W), or tantalum (Ta)). The gate electrode 18 may be a gate line GL. The first direction (the Y direction) may be a direction parallel to the gate line GL.

A gate insulating layer 17 may be on a bottom side surface of the gate electrode 18 and on the semiconductor substrate 12. The gate insulating layer 17 may include at least one of a high-k material, an oxide, a nitride, and an oxynitride. The high-k material may be an insulating material having a greater dielectric constant than the nitride. For example, the high-k material may include at least one of a plurality of dielectric metal oxides such as hafnium oxide and aluminum oxide.

The semiconductor device 10 may include impurity regions 20 which are separated from each other by the gate electrode 18 in a second direction (an X direction) perpendicular to the first direction (the Y direction) on the semiconductor substrate 12. The second direction (the X direction) may be perpendicular to the first direction (the Y direction) and may be perpendicular to the gate electrode 18 or the gate line GL. The impurity region 20 may be a region where p-type impurities, for example, boron (B), are injected into the semiconductor substrate 12. The impurity region 20 may be a region where n-type impurities, for example, phosphorus (P) or arsenic (As), are injected into the semiconductor substrate 12.

The impurity region 20 may include a source region S and a drain region D. The source region S and the drain region D may be respectively a p-type source region and a p-type drain region, and accordingly, the semiconductor device 10 may form a p-type MOS transistor. The source region S and the drain region D may respectively be an n-type source region and an n-type drain region, and accordingly, the semiconductor device 10 may form an n-type MOS transistor.

The multi-liner layer 30 may be arranged on the inside wall of the trench 13, and may physically and electrically separate the active region AR from the trench isolation layer 16, as described above.

In addition, the multi-liner layer 30 may be adjacent to the gate electrode 18 and the gate insulating layer 17 in the first direction parallel to the gate electrode 18, and may be arranged in an area adjacent to edges of the source and drain regions S and D, as illustrated as reference numbers 14a, through 14d in FIGS. 1 and 2.

In addition, the multi-liner layer 30 may be adjacent to the gate electrode 18 and the gate insulating layer 17 in the first direction parallel to the gate electrode 18, and may be arranged in an area adjacent to top side edges of the source and drain regions S and D, as illustrated by reference numbers 14a through 14d in FIGS. 1 and 2.

If the multi-liner layer 30 is arranged in an area adjacent to edges of the source and drain regions S and D in the first direction parallel to the gate electrode 18, when the semiconductor device 10 operates, charges, for example, in the form of electrons, may not be trapped in the third liner layer 28 having a high charge trap density but may be trapped in the second liner layer 26 having a low charge trap density.

Accordingly, the semiconductor device 10 may effectively separate the active region AR from the trench isolation layer 16, both physically and electrically, and at the same time, when the semiconductor device 10 operates, a “punch through” phenomenon due to charges, for example, in the form of hot electrons, may be reduced, and thus characteristics of a transistor may be improved. “Punch-through” typically takes place when the junction voltage decreases and allows a large flow of electrons or other charges through the liner.

Below, an example embodiment will be described in which the semiconductor device 10 of FIGS. 1 through 3 is applied, for example, to a dynamic random access memory (DRAM) device, An example will be described in which a buried channel array transistor (BCAT) is included as a method of reducing MOS transistors among the DRAM devices.

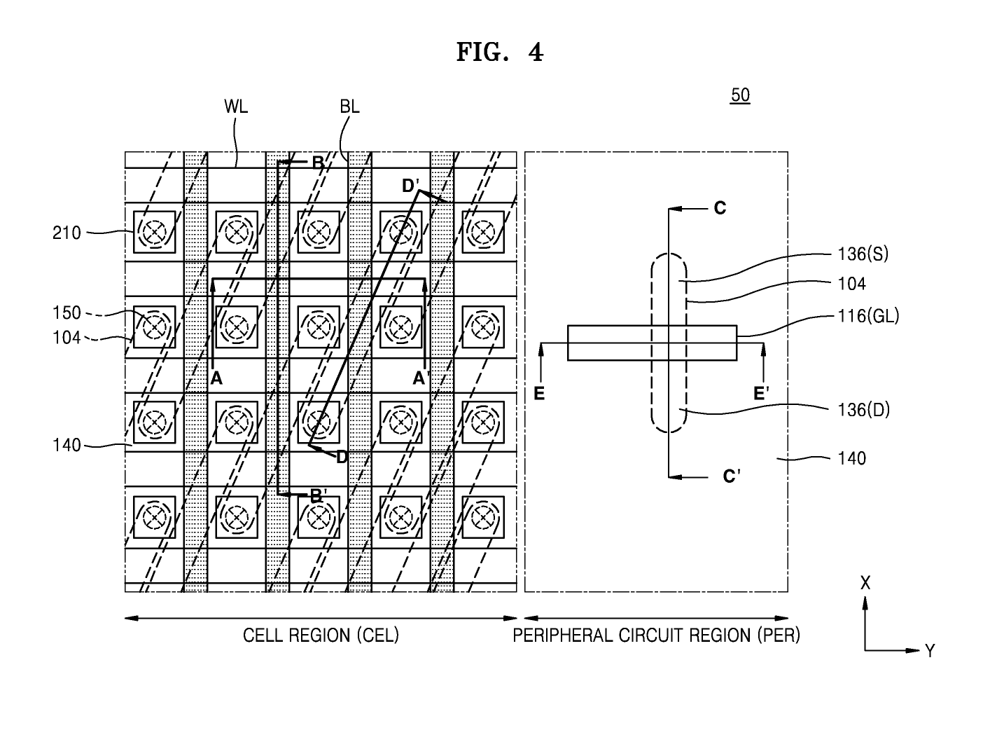

FIG. 4 is a plan view of a semiconductor device 50 according to an example embodiment of the inventive concepts.

The semiconductor device 50 may include a cell region CEL and a peripheral circuit region PER. The BCAT may be in the cell region CEL and an un-buried channel array transistor may be in the peripheral circuit region PER.

An active region 104 may be in the cell region CEL and the peripheral circuit region PER. The active region 104 may be defined by the trench isolation layer 16. The active region 104 in the cell region CEL may be arranged in a diagonal direction. The active region 104 in the cell region CEL may be arranged not only in the diagonal direction as illustrated in FIG. 4 but also in various other configurations.

A word line WL may be arranged in the first direction (the Y direction) in the cell region CEL. The word line WL may be used as a cell gate electrode as described below. A bit line BL may be arranged in the second direction (the X direction) in the cell region CEL. An information storage element 210, for example, a capacitor, connected to the bit line BL via a second contact plug 150 may be in the active region 104 of the cell region CEL. Descriptions of the second contact plug 150 and the information storage element 210 will be provided later.

The active region 104 in the peripheral circuit region PER may be parallel to the second direction (the X direction). The active region 104 in the peripheral circuit region PER may be arranged not only in a direction parallel to the second direction in FIG. 4 but also in various other configurations, for example, in a diagonal direction. A peripheral circuit gate electrode 116 crossing the active region 104 may be arranged in the peripheral circuit region PER. The peripheral circuit gate electrode 116 may be a peripheral circuit gate line GL. An impurity region 136 may be in the active region 104, on both sides of the peripheral circuit gate electrode GL 116 in the second direction (the X direction). The impurity region 136 may include the source region S and the drain region D. A reference number 140 in the cell region CEL and the peripheral circuit region PER may denote a second insulating layer.

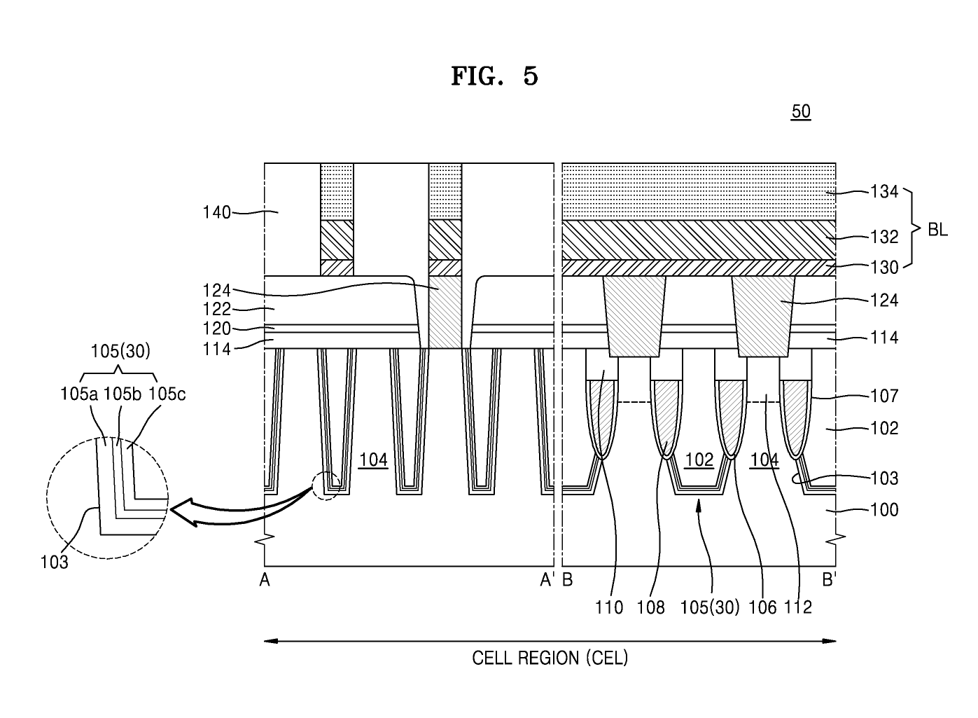

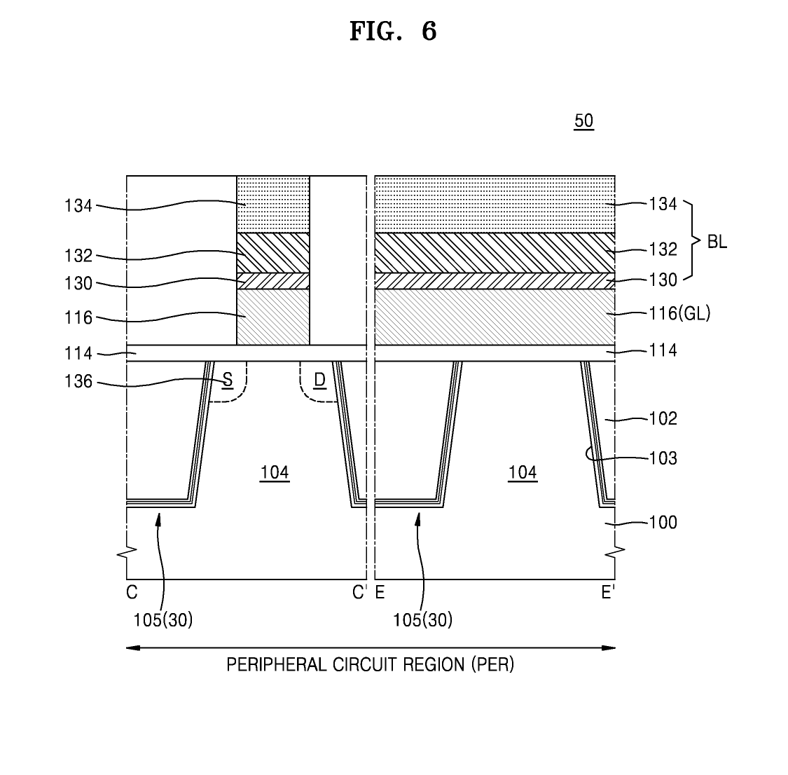

FIG. 5 is a combination of cross-sectional views of the semiconductor device 50, respectively cut along lines A-A′ and B-B′ in FIG. 4, according to an example embodiment of the inventive concepts. FIG. 6 is a combination of cross-sectional views of the semiconductor device 50, respectively cut along lines C-C′ and E-E′ in FIG. 4, according to an example embodiment of the inventive concepts.

The semiconductor device 50 may include a semiconductor substrate 100 including the cell region CEL and the peripheral circuit region PER. The semiconductor substrate 100 may include a semiconductor material. For example, the semiconductor substrate 100 may include at least one of Si and Ge.

A trench isolation layer 102 defining the active region 104 may be in the semiconductor substrate 100. The trench isolation layer 102 may be the TIR. The trench isolation layer 102 may be a shallow trench isolation (STI) layer, but not limited thereto.

The trench isolation layer 102 may include an insulating layer. For example, the trench isolation layer 102 may include at least one of silicon oxide, silicon nitride, and silicon oxynitride.

A multi-liner layer 105 may be on an inside wall of the trench isolation layer 102. The multi-liner layer 105 may include a first liner layer 105a on an inside wall of a trench 103, a second liner layer 105b on the first liner layer 105a, and a third liner layer 105c on the second liner layer 105b. In an example embodiment, the multi-liner layer 105 may include a first liner layer 105a on an inside wall of a trench 103, and a second liner layer 105b on the first liner layer 105a.

The multi-liner layer 105 may correspond to the multi-liner layer 30 previously described in FIGS. 1 through 3. In other words, the first through third liner layers 24, 26, and 28 in FIGS. 1 through 3 may respectively correspond to the first through third liner layers 105a, 105b, and 105c in FIGS. 5 and 6. The first liner layer 105a may include a silicon oxide layer (SiₓO_{y}, where x and y are positive integers), the second liner layer 105b may include a silicon oxynitride layer (SiOₓN_{y}, where x and y are positive integers), and the third liner layer 105c may include a silicon nitride layer (SiₓN_{y}, where x and y are positive integers). Descriptions of overlapping content will be omitted.

A cell trench 107 may be inside the semiconductor substrate 100 in the cell region CEL. In a plane defined by the surface of the semiconductor device 50, the cell trench 107 may have a line shape which extends in the first direction (the Y direction) in FIG. 4, and crosses the active region 104 and the trench isolation layer 102. A cell gate electrode 108 may be inside the cell trench 107.

In a plane defined by the surface of the semiconductor device 50, the cell gate electrode 108 may have a line shape which extends in the first direction (the Y direction) in FIG. 4, and crosses the active region 104 and the trench isolation layer 102. A level of a top side surface of the cell gate electrode 108 may be lower than the level of a top side surface of the semiconductor substrate 100. Accordingly, the cell gate electrode 108 may be buried inside the cell trench 107.

The cell gate electrode 108 may include a conductive material. For example, the cell gate electrode 108 may include at least one of a doped semiconductor, a conductive metal nitride (for example, TiN, TaN, and WN), and a metal (for example, Ru, Ir, Ti, and W).

A cell gate insulating layer 106 may be on a bottom side surface of the cell gate electrode 108. The cell gate insulating layer 106 may include at least one of an oxide, a nitride, an oxynitride, and a high-k material. The high-k material may be an insulating material having a greater dielectric constant than the nitride. For example, the high-k material may include at least one of dielectric metal oxides such as hafnium oxide and aluminum oxide.

The cell gate insulating layer 106 may have a U-shape and may contact an entire inner side surface of the cell trench 107. A cell gate capping pattern 110 may be on the cell gate electrode 108. The cell gate capping pattern 110 may include an insulating material. For example, the cell gate capping pattern 110 may include at least one of the oxide, the nitride, and the oxynitride.

A cell impurity region 112 may be on two sides of the cell trench 107 in the active region 104. A bottom side surface of the cell impurity region 112 may be at a certain depth from a top side surface of the active region 104. The cell impurity region 112 may be in contact with a side wall of the cell trench 107. The cell impurity region 112 may include an area having impurities doped therein. The impurities may include, for example, As, P, or boron (B). The bottom side surface of the cell impurity region 112 may be higher than the bottom side surface of the cell trench 107.

A peripheral circuit gate insulating layer 114 may be on the semiconductor substrate 100. The peripheral circuit gate insulating layer 114 may include at least one of an oxide, a nitride, an oxynitride, and a high-k material. The high-k material may be an insulating material having a greater dielectric constant than the nitride. For example, the high-k material may include at least one of a plurality of dielectric metal oxides such as hafnium oxide and aluminum oxide.

The peripheral circuit gate electrode 116 may be on the peripheral circuit gate insulating layer 114 of the active region 104 of the peripheral circuit region PER. The peripheral circuit gate electrode 116 may cross the active region 104 and the trench isolation layer 102 on the semiconductor substrate 100 in the peripheral circuit region PER, as illustrated in FIGS. 4 and 6.

The peripheral circuit gate electrode 116 may include at least one of a conductive material (for example, polysilicon), a doped semiconductor, a conductive metal nitride (for example, TiN, TaN, and WN), and a metal (for example, Ru, Ir, Ti, and W). The peripheral circuit gate electrode 116 may be the peripheral circuit gate line GL.

A peripheral circuit impurity region 136 may be on two sides of the peripheral circuit gate electrode 116 in the active region 104. The peripheral circuit impurity region 136 may include the source region S and the drain region D. A bottom side surface of the peripheral circuit impurity region 136 may be at a certain depth from the top side surface of the active region 104. The peripheral circuit impurity region 136 may include an area having impurities doped therein. The impurities may include, for example, P or B. The bottom side surface of the peripheral circuit impurity region 136 may be higher than the bottom side surface of the trench isolation layer 102.

An etching stopping layer 120 may be on the peripheral circuit gate insulating layer 114 in the cell region CEL. The etching stopping layer 120 may include at least one of an oxide, a nitride, and an oxynitride. The etching stopping layer 120 may include a material having a greater etching selectivity than the peripheral circuit gate insulating layer 114.

A first insulating layer 122 may be on the etching stopping layer 120 in the cell region CEL. The first insulating layer 122 may be single-layered or multi-layered. The first insulating layer 122 may include at least one of an oxide, a nitride, and an oxynitride. The first insulating layer 122 may include a material having a higher etching selectivity than the etching stopping layer 120. A first contact plug 124 may be arranged which penetrates through the first insulating layer 122, the etching stopping layer 120, and the peripheral circuit gate insulating layer 114.

The first contact plug 124 may be electrically connected to the active region 104 between cell gate electrodes 108. The first contact plug 124 may include a conductive material. For example, the first contact plug 124 may include at least one of a conductive material (for example, polysilicon), a metal-semiconductor compound (for example, tungsten silicide), a conductive metal nitride (for example, TiN, TaN, and WN), and a metal (for example, Ru, Ir, Ti, and W).

The bit line BL electrically connected to the first contact plug 124 may be on the first insulating layer 122 in the cell region CEL. The hit line BL may include a barrier pattern 130, a metal pattern 132, and a capping pattern 134, which are laminated, for example sequentially laminated, on the first insulating layer 122.

The bit line BL may be electrically connected to the peripheral circuit gate electrode 116 in the peripheral circuit region PER. The barrier pattern 130 may include a conductive metal nitride (for example, TiN, TaN, and WN). The metal pattern 312 may include a metal (for example, Ru, Ir, Ti, W, and Ta). The capping pattern 134 may include at least one of an oxide, a nitride, and an oxynitride.

A second insulating layer 140 exposing an upper surface of the bit line BL may be on the first insulating layer 122. The second insulating layer 140 may be single-layered or multi-layered. The second insulating layer 140 may include at least one of an oxide, a nitride, and an oxynitride.

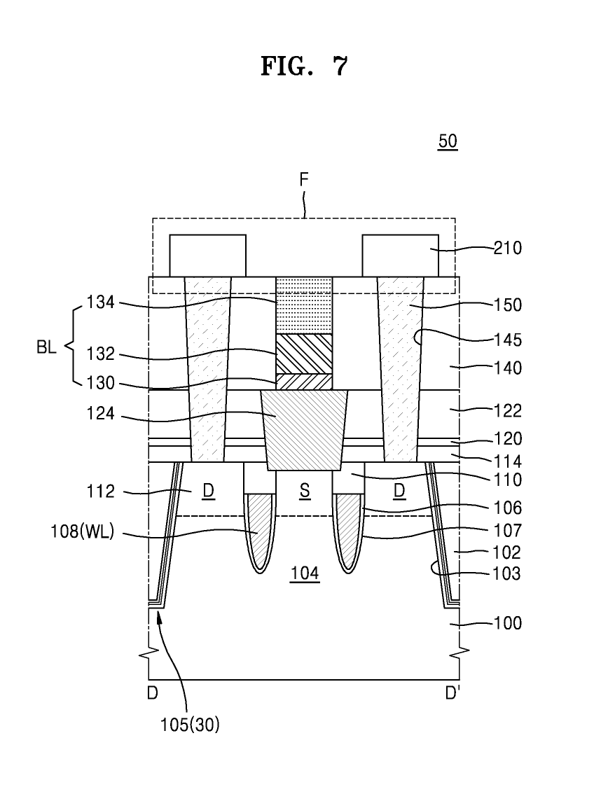

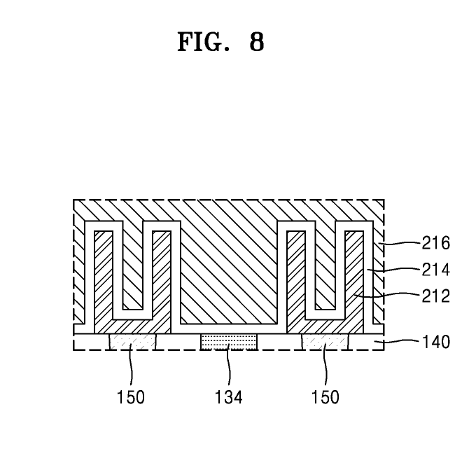

FIG. 7 is a cross-sectional view of the semiconductor device 50, cut along lines D-D′ in FIG. 4, according to an example embodiment of the inventive concepts. FIG. 8 is an enlarged cross-sectional view of a portion F in FIG. 7.

The cell impurity region 112 may be on two sides of the cell trench 107 in the active region 104. The cell impurity region 112 may include the source region S and the drain region D. One source region S and a pair of drain regions may be in the active region 104. The source region S, which is common, may be between pair of cell gate electrodes 108 in the active region 104.

A second contact plug 150 may be arranged which penetrates a second insulating layer 140, the first insulating layer 122, the etching stopping layer 120, and the peripheral circuit gate insulating layer 114. The second contact plug 150 may be in contact with the drain region D adjacent to the cell trench 107. The second contact plug 150 may include a conductive material. For example, the second contact plug 150 may include at least one of a conductive material (for example, polysilicon), a metal-semiconductor compound (for example, tungsten silicide), a conductive metal nitride (for example, TiN, TaN, and WN), and a metal (for example, Ru, Ir, Ti, and W).

The information storage element 210 electrically connected to the second contact plug 150 may be on the second insulating layer 140. The information storage element 210 may have various configurations. The information storage element 210 may be a capacitor as illustrated in FIG. 8.

The information storage element 210 may include a bottom electrode 212 (or a storage node) in contact with the second contact plug 150. The bottom electrode 212 may have a cylindrical shape. In other words, the bottom electrode 212 may include a flat portion in contact with the second contact plug 150 and a side wall portion upwardly extending from edges of the flat portion.

The bottom electrode 212 may include a conductive material. For example, the bottom electrode 212 may include at least one of a doped semiconductor, a conductive metal nitride (for example, TiN, TaN, and WN), a metal (for example, Ru, Ti, and W), and a conductive metal oxide (for example, iridium oxide).

A dielectric layer 214 may be conformally arranged on a surface of the bottom electrode 212. The dielectric layer 214 may cover an entire surface of the bottom electrode 212. The dielectric layer 214 may cover a portion of the top side surface of the second insulating layer 140. The dielectric layer 214 may include at least one of an oxide, a nitride, an oxynitride, and a high-k material.

A top electrode 216 coveting the dielectric layer 214 may be on the second insulating layer 140. The top electrode 216 may include a conductive material. For example, the top electrode 216 may include at least one of a doped semiconductor, a metal, a conductive metal nitride, and a metal silicide.

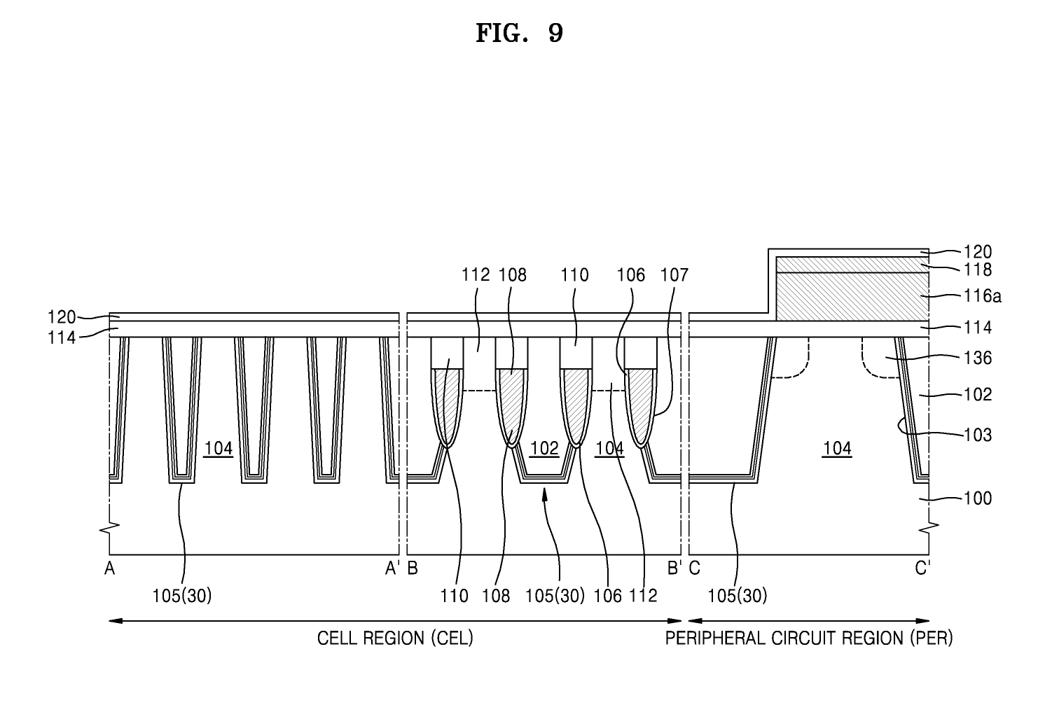

FIGS. 9 through 13 are combinations of cross-sectional views of the semiconductor device 10, cut along the lines A-A′, B-B′, and C-C′ in FIG. 1, for illustrating a manufacturing method thereof, according to an example embodiment of the inventive concepts.

Referring to FIG. 9, the semiconductor substrate 100 including the cell region CEL and the peripheral circuit region PER may be prepared. The trench 103 may be formed in the semiconductor substrate 100. The multi-liner layer 105 may be formed on the inside wall of the trench 103. Descriptions of the multi-liner layer 105 have been provided above and will be omitted below. The trench isolation layer 102 may be formed on the multi-liner layer 105 inside the trench 103 for defining the active region 104.

After an insulating layer filling the inside of the trench 103 is formed on the multi-liner layer 105 in the trench 103, the trench isolation layer 102 may be formed by etching the insulating layer so that the top side surface of the semiconductor substrate 100 is exposed.

The cell trench 107 may be formed in the semiconductor substrate 100 of the cell region CEL. The cell trench 107 may be formed by forming a mask pattern (not shown) on the semiconductor substrate 100 and via an etching process using the mask pattern as an etching mask. An etching process may include a dry etching process.

The cell gate insulating layer 106 may be conformally formed on the top side surface of the semiconductor substrate 100 and on the inside surface of the cell trench 107. The cell gate insulating layer 106 may be formed via an oxidation process. In this case, the oxidation process may be executed at leak one time. In other words, the cell gate insulating layer 106 may be formed by executing the oxidation process one time or several times repeatedly. Alternatively, the cell gate insulating layer 106 may be formed via the CVD process or the ALD process.

A cell gate electrode layer filling at least a bottom portion of an entire inside portion of the cell trench 107 may be formed on a front side surface of the semiconductor substrate 100. The cell gate electrode layer may be formed via a physical vapor deposition (PVD) process or the ALD process.

Prior to formation of the cell gate electrode layer, a nitridation process or a surface treatment process using ozone may be executed on the semiconductor substrate 100 having the cell gate insulating layer 106 formed therein. Such surface treatment processes may reduce occurrence of layers caused by impurities on an interface surface between the cell gate insulating layer 106 and the cell gate electrode layer, and may improve reliability and electrical characteristics of a semiconductor device.

The cell gate electrode 108 may be formed by etching the cell gate electrode layer. The level of the top side surface of the cell gate electrode 108 may be lower than the level of the top side surface of the semiconductor substrate 100. Accordingly, the cell gate electrode 108 may be formed inside the cell trench 107. The cell gate electrode 108 may be formed by at least one of, for example, the dry etching process and a chemical mechanical polishing (CMP) process. In this case, the cell gate insulating layer 106 may have a U-shaped cross-section covering the side wall and the bottom side surface of the cell gate electrode 108.

The cell gate capping pattern 110 may be formed on the cell gate electrode 108, The cell gate capping pattern 110 may be formed by forming a cell gate capping layer on the front side surface of the substrate 100 and by etching the cell gate capping layer until the top side surface of the semiconductor substrate 100 is exposed. The cell gate capping layer may be formed via the CVD process. The etching process may be executed by, for example, at least one of the CMP process, the dry etching process, and a wet etching process.

The cell impurity region 112 adjacent to the cell trench 107 may be formed on two sides of the cell trench 107 in the active region 104. The cell impurity region 112 may include the source and drain regions. The lower surface of the cell impurity region 112 may be formed to have a certain depth from the top side surface of the active region 104. The cell impurity region 112 may be in contact with the side wall of the cell trench 107. The cell impurity region 112 may be formed via a process of injecting impurities into the active region 104. The impurities may include, for example, P or B. According to an example embodiment of the inventive concepts, the bottom side surface of the cell impurity region 112 may be higher than the bottom side surface of the cell trench 107.

The peripheral circuit gate insulating layer 114 may be formed on the front surface of the semiconductor substrate 100. The peripheral circuit gate insulating layer 114 may be thicker than the cell gate insulating layer 106. The peripheral circuit gate insulating layer 114 may be multi-layered.

A peripheral circuit gate electrode layer 116a and a mask layer 118 may be laminated, for example sequentially laminated on the peripheral circuit gate insulating layer 114 in the active region 104 of the peripheral circuit region PER. The peripheral circuit gate electrode layer 116a may include at least one of a semiconductor material (for example, a polysilicon), a doped semiconductor, a conductive metal nitride (for example, TiN, TaN, and WN), and a metal (for example, Ru, Ir, Ti, W, and Ta). The mask layer 118 may include at least one of an oxide, a nitride, and an oxynitride.

Next, the etching stopping layer 120 may be formed on the front side surface of the semiconductor substrate 100. The etching stopping layer 120 may include at least one of an oxide, a nitride, and an oxynitride. The etching stopping layer 120 may include a material having a greater etching selectivity than the peripheral circuit gate insulating layer 114.

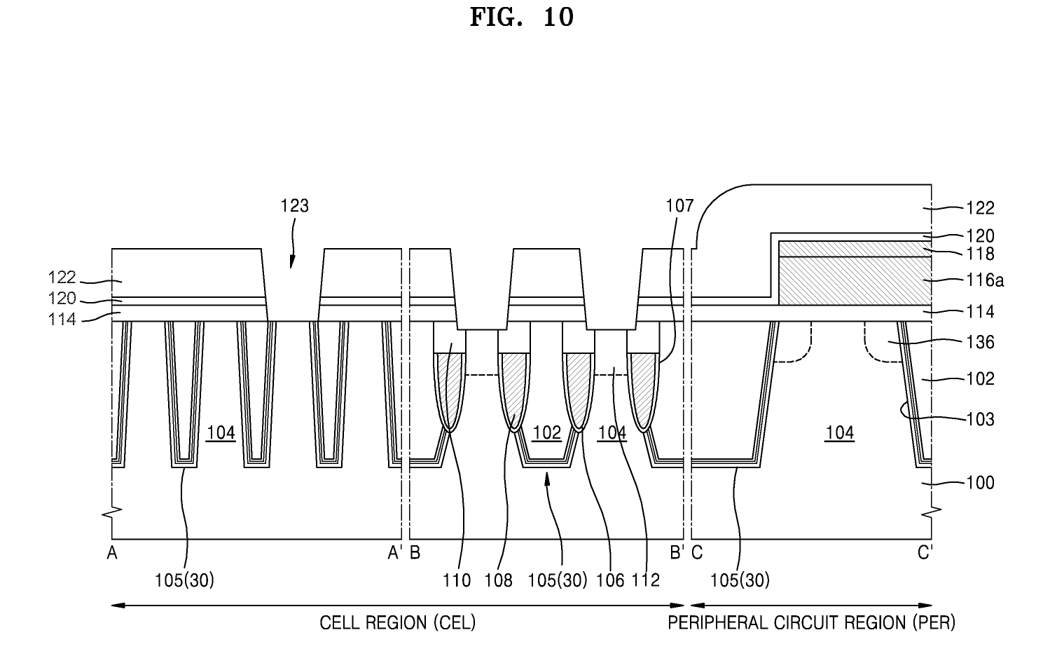

Referring to FIG. 10, the first insulating layer 122 may be formed on the top side surface of the substrate 100 having the etching stopping layer 120 formed thereon. The first insulating layer 122 may include at least one of an oxide, a nitride, and an oxynitride. The first insulating layer 122 may include a material having a higher etching selectivity than the etching stopping layer 120. The opening 123 may be formed which penetrates through the first insulating layer 122, the etching stopping layer 120, and the peripheral circuit gate insulating layer 114, and exposes the common source region in the cell region CEL. The opening 123 may be formed by forming a mask pattern (not shown) on the first insulating layer 122 and by executing the dry etching process using the mask pattern as a mask on the first insulating layer 122.

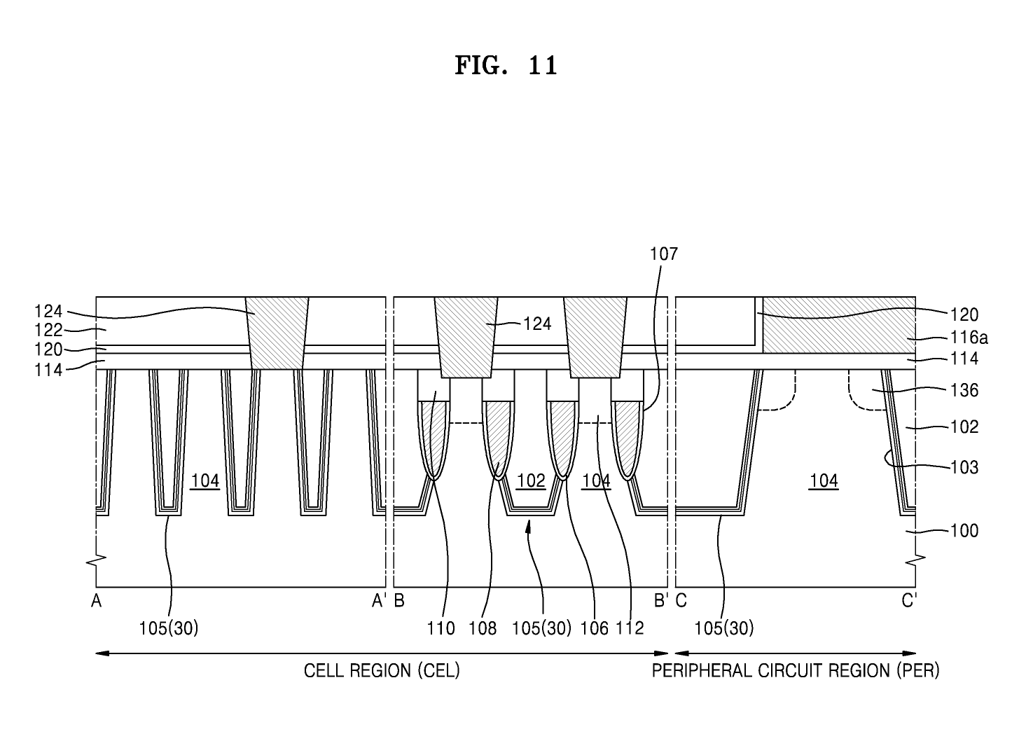

Referring to FIG. 11, the first contact plug 124 may be formed in the opening 123. The first contact plug 124 may include a conductive material. For example, the first contact 124 may include at least one of a conductive material (for example, polysilicon), a metal-semiconductor compound (for example, tungsten silicide), a conductive metal nitride (for example, TiN, TaN, and WN), and a metal (for example, Ru, Ir, Ti, and W).

The first contact plug 124 may be formed by forming a conductive layer filling the opening 123 in the first insulating layer 122 and by etching the conductive layer until the top side surface of the first insulating layer 122 is exposed. Forming the conductive layer may be executed via, for example, the CVD process or the PVD process. The etching process may be executed via, for example, at least one of the dry etching process and the CMP process. In this case, the first contact plug 124 may have a lower level than the top side surface of the first insulating layer 122.

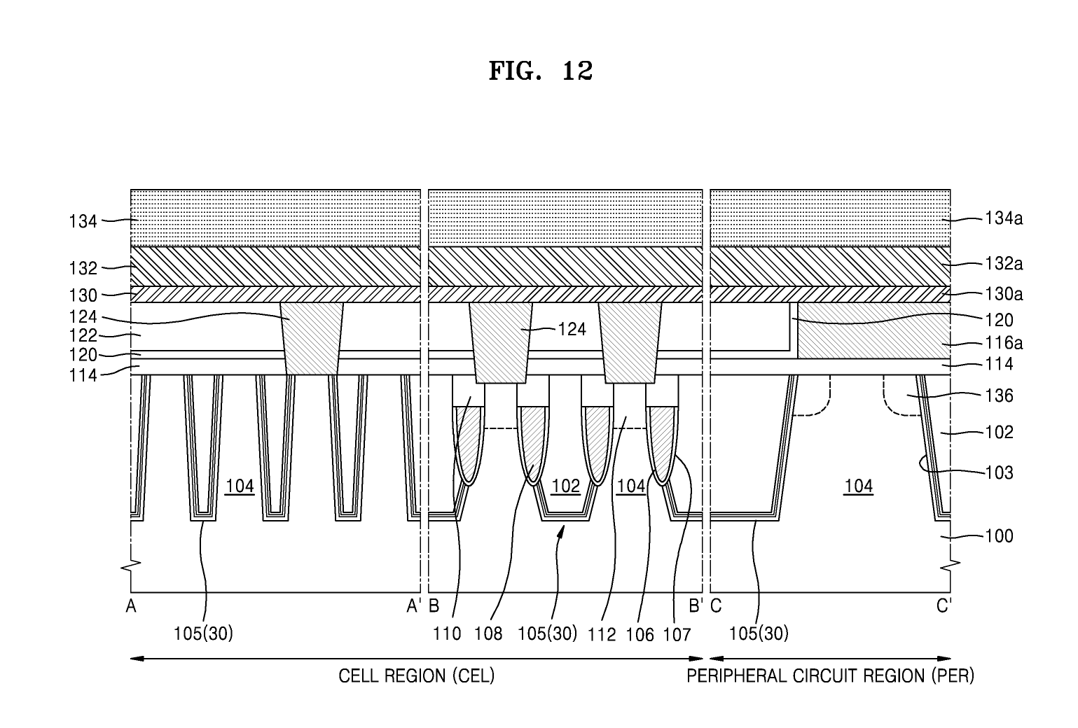

Referring to FIG. 12, in a subsequent process, a barrier layer 130a, a metal layer 132a, and a capping layer 134a, which compose the bit line BL, may be formed on the front side surface of the semiconductor substrate 100 on which the first contact plug 124 and the peripheral circuit gate electrode layer 116a are formed.

The barrier layer 130a may include a conductive metal nitride (for example, TiN, and WN). The metal layer 132a may include a metal (for example, Ru, Ir, Ti, W, and Ta). The capping layer 134a may include at least one of an oxide, a nitride, and an oxynitride.

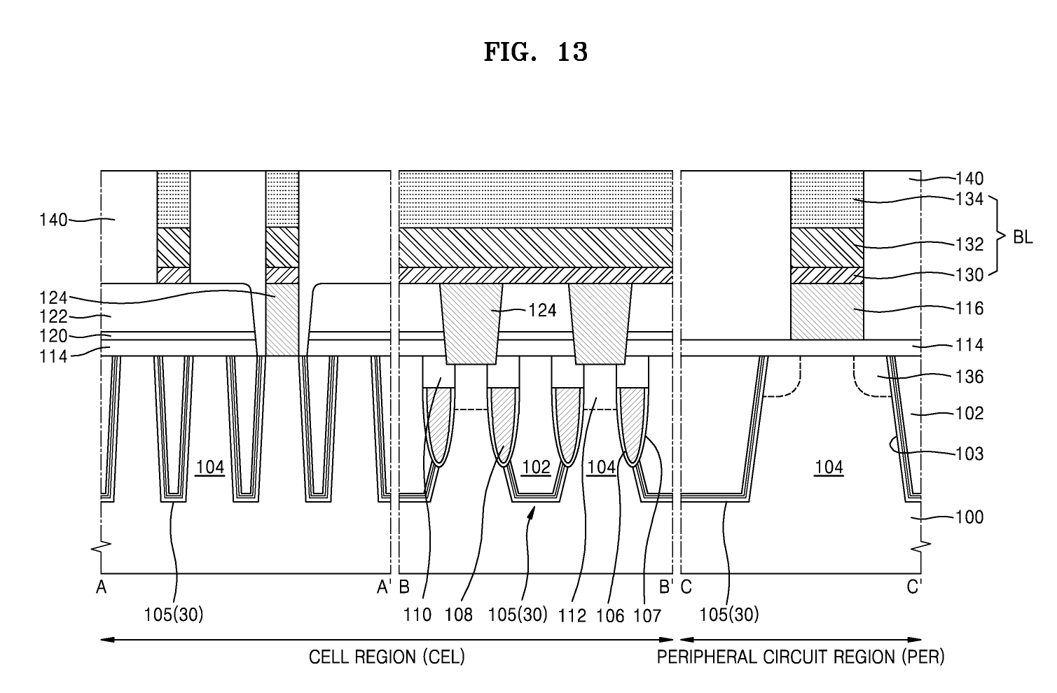

Referring to FIG. 13, the bit line BL and the peripheral circuit gate electrode 116 may be formed. As the first contact plug 124 in the cell region CEL and the peripheral circuit gate electrode 116 in the peripheral circuit region PER are electrically connected, the bit line BL may be formed in which the barrier pattern 130, the metal pattern 132, and the capping pattern 134 are laminated, for example sequentially laminated.

The bit line BL may be formed by patterning the capping layer 134a, the metal layer 132a, and the barrier layer 130a. Alternatively, the bit line BL may be formed via, for example, a damascene process. The bit line BL may be formed by forming the second insulating layer 140 including the opening 123 in the first insulating layer 122 and filling, for example sequentially filling the opening 123 with the barrier pattern 130, the metal pattern 132, and the capping pattern 134. The peripheral circuit gate electrode 116 may be formed by pattering the peripheral circuit gate electrode layer 116a.

The peripheral circuit impurity region 136 may be formed on two sides of the peripheral circuit gate electrode 116 in the active region AR 104. The peripheral circuit impurity region 136 may include the source and drain areas S and D. The bottom side surface of the peripheral circuit impurity region 136 may be at a certain depth from the top side surface of the active region AR 104.

The peripheral circuit impurity region 136 may be formed by forming a photoresist pattern (not shown), exposing the peripheral circuit region PER, on the semiconductor substrate 100 having the bit line BL formed thereon, and then, via a doping process of injecting impurities into the active region 104 on two sides of the peripheral circuit gate electrode 116 by an ion injection process using the bit line BL on the peripheral circuit gate electrode 116 as a mask. The impurities may include, for example, As, P, and B. The bottom side surface of the peripheral circuit impurity region 136 may be higher than the bottom side surface of the trench isolation layer 102.

The second insulating layer 140 exposing the top side surface of the bit line BL may be formed on the first insulating layer 122, as illustrated in FIG. 7. The second insulating layer 140 may be formed via the CVD process. The second insulating layer 140 may include at least one of an oxide, a nitride, and an oxynitride. A contact hole 145 may be formed which penetrates through the second insulating layer 140, the first insulating layer 122, the etching stopping layer 120, and the peripheral circuit gate insulating layer 114, and exposes the drain regions D. The contact hole 145 may be formed by forming a mask pattern (not shown) on the second insulating layer 140, and by executing the dry etching process using the mask pattern as a mask on the second insulating layer 140, the first insulating layer 122, the etching stopping layer 120, and the peripheral circuit gate insulating layer 114.

The second contact plug 150 may be formed inside the contact hole 145. The second contact plug 150 may include a conductive material. For example, the second contact plug 150 may include at least one of a semiconductor material (for example, a polysilicon), a metal-semiconductor compound (for example, tungsten silicide), a conductive metal nitride (for example, TiN, TaN, and Wn), and a metal (for example, Ti, W, and Ta).

The second contact plug 150 may be formed by forming a conductive layer filling the contact hole 145 on the second insulating layer 140, and etching the conductive layer until the top side surface of the second insulating layer 142 is exposed. Forming the conductive layer may be executed via the CVD process or the PVD process. The etching process may be executed via the dry etching process or the CMP process.

The information storage element 210 electrically connected to the second contact plug 150 may be formed on the second insulating layer 140. Since the information storage element 210 has been described above, further descriptions thereof are omitted.

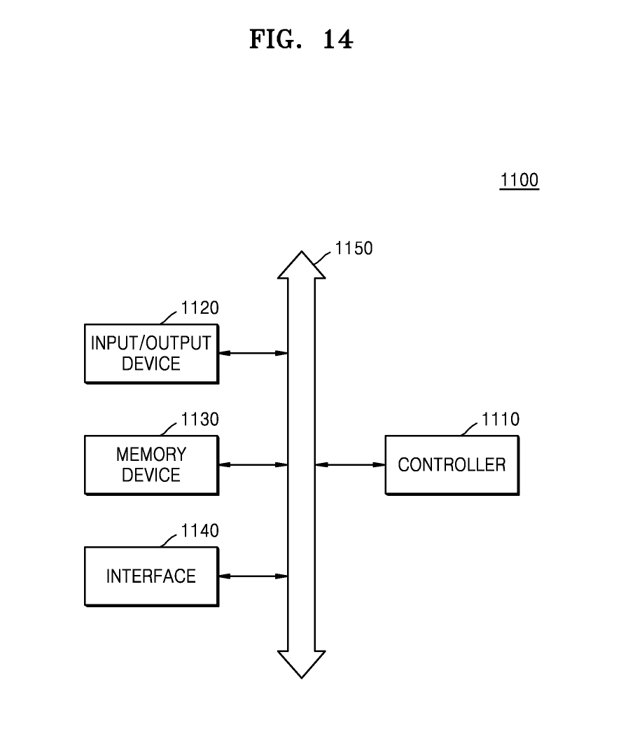

FIG. 14 is a block diagram of a memory system 1100 including a semiconductor device, according to an example embodiment of the inventive concepts.

The memory system 1100 may be applied to, for example, personal digital assistants (PDAs), portable computers, web tablets, wireless phones, mobile phones, digital music players, memory cards, or other devices capable of transmitting/receiving information in a wireless environment.

The memory system 1100 may include a controller 1110, an input/output device 1120 such as a keypad or a keyboard, a memory device 1130, an interface 1140, and a bus 1150. The memory device 1130 and the interface 1140 may communicate with each other via the bus 1150.

The controller 1110 may include at least one microprocessor, a digital signal processor, a microcontroller, or other processing devices similar to or the same as these devices. The memory device 1130 may store commands executed by the controller 1110. The input/output device 1120 may receive data or signals from the outside of the memory system 1100 or output data or signals to the outside of the memory system 1100. For example, the input/output device 1120 may include the keyboard, the keypad, or a display.

The memory device 1130 may include a semiconductor device according to an example embodiment of the inventive concepts. In addition, the memory device 1130 may further include a volatile memory which is accessible at any time, and various other types of memory. The interface 1140 may transmit data to a communication network or receive data from the communication network.

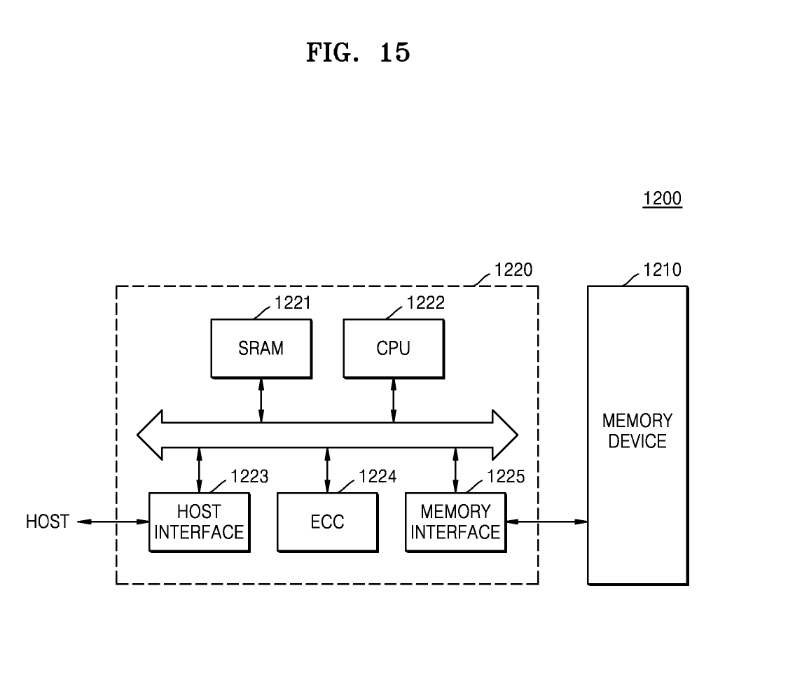

FIG. 15 is a block diagram of a memory card 1200 including a semiconductor device, according to an example embodiment of the inventive concepts.

The memory card 1200 for supporting a higher data storage capability may include a memory device 1210 including a semiconductor device according to the inventive concepts. The memory card 1200 may include the memory controller 1220 controlling an overall data exchange between a host and the memory device 1210.

A static random access memory (SRAM) 1221 may function as an operating memory of a central processing unit (CPU) 1222 which is a processing unit. A host interface 1223 may have a data exchange protocol for the host connected to the memory card 1200. An error correction coding (ECC) block 1224 may detect and correct errors included in data which is read from the memory device 1210 and has multi-bit characteristics. A memory interface 1225 may interface with the memory device 1210. The CPU 1222 may execute an overall control operation for data exchange of the memory controller 1220. Although not illustrated in the drawing, it will be clearly understood by one of ordinary skill in the art that the memory card 1200 according to the inventive concepts may further include a read-only memory (ROM) storing signal data for interfacing with the host. A highly integrated memory system may be provided according to a semiconductor device, a memory card, or a memory system of the inventive concepts. Especially, a semiconductor device of the inventive concepts may be provided to a memory system such as a solid state drive (SSD) which is recently under an active research. In this case, the highly integrated memory system may be realized.

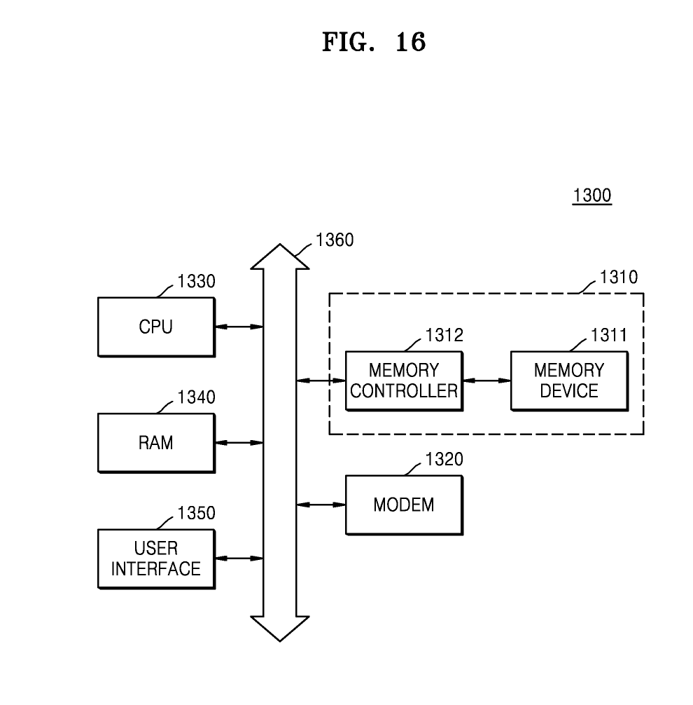

FIG. 16 is a block diagram of an information processing system 1300 including a semiconductor device, according to an example embodiment of the inventive concepts.

The information processing system 1300 may be used in mobile devices or desktop computers. The information processing system 1300 may include a memory system 1310 which includes a memory device 1311 and includes a memory controller 1312, according to an example embodiment of the inventive concepts.

The information processing system 1300 may include a modulator and demodulator (MODEM) 1320 electrically connected to a system bus 1360, a CPU 1330, a RAM 1340, and a user interface 1350. The memory system 1310 may store data processed by the CPU 1330 or data input from the outside. In this case, the memory system 1310 may include the SSD, and the information processing system 1300 may stably store mass data in the memory system 1310. In addition, the memory system 1310, in accordance with an increase in reliability, may reduce resources needed for error correction, and thus, may provide a high-speed data exchange capability to the information processing system 1300. Although not illustrated in the drawing, it will be dearly understood by one of ordinary skill in the art that the information processing system 1300 may further include an application chipset, an image signal processor (ISP), an input/output device, etc.

While the inventive concepts have been particularly shown and described with reference to example embodiments thereof, it will be understood that various changes in form and details may be made therein without departing from the spirit and scope of the following claims.

1. A semiconductor device comprising:
a semiconductor substrate;
a trench isolation layer on the semiconductor substrate and configured to define an active region; and
a multi-liner layer on an inside wall of a trench including the trench isolation layer,
the multi-liner layer including a first liner layer on the inside wall of the trench, a second liner layer on the first liner layer, and a third liner layer on the second liner layer.

2. The semiconductor device of claim 1, wherein a charge trap density of the second liner layer is higher than a charge trap density of the first liner layer and lower than a charge trap density of the third liner layer.

3. The semiconductor device of claim 1, wherein the second liner layer includes a charge trap layer in which charge can be trapped.

4. The semiconductor device of claim 1, wherein the first liner layer includes a silicon oxide layer (SiₓO_{y}, where x and y are positive integers), the second liner layer includes a silicon oxynitride layer (SiOₓN_{y}, where x and y are positive integers), and the third liner layer includes a silicon nitride layer (SiₓN_{y}, where x and y are positive integers).

5. The semiconductor device of claim 4, wherein the first liner layer includes the silicon oxide layer formed via a thermal oxidation method, and the second liner layer and the third liner layer include respectively the silicon oxynitride layer (SiOₓN_{y}, where x and y are positive integers) and the silicon nitride layer (SiₓN_{y}, where x and y are positive integers), which are formed via a deposition method.

6. The semiconductor device of claim 1, wherein:
the trench isolation layer includes an insulating layer inside the trench; and
the active region includes a portion of the semiconductor substrate.

7. The semiconductor device of claim 1, further comprising:
a gate electrode crossing the active region in a first direction and extending to the trench isolation layer above the semiconductor substrate,
a gate insulating layer below a gate electrode on the semiconductor substrate, and
a source region and a drain region which are separated from each other by the gate electrode in a second direction perpendicular to the first direction on the semiconductor substrate.

8. The semiconductor device of claim 7, wherein the multi-liner layer is adjacent to the gate electrode and the gate insulating layer in the first direction parallel to the gate electrode and is in an area adjacent to edges of the source and drain regions.

9. The semiconductor device of claim 7, wherein the multi-liner layer is adjacent to the gate electrode and the gate insulating layer in the first direction parallel to the gate electrode, and is vertical in an area adjacent to top portions of edges of the source and drain regions.

10-15. (canceled)

16. A semiconductor device comprising:
a semiconductor substrate;
a trench isolation layer on the semiconductor substrate and configured to define an active region; and
a multi-liner layer on an inside wall of a trench including the trench isolation layer, the multi-liner layer including a first liner layer on the inside wall of the trench, and a second liner layer on the first liner layer.

17. The semiconductor device of claim 16, wherein a charge trap density of the second liner layer is higher than a charge trap density of the first liner layer.

18. The semiconductor device of claim 16, wherein the second liner layer includes a charge trap layer in which charge can be trapped.

19. The semiconductor device of claim 16, wherein the first liner layer includes a silicon oxide layer (SiₓO_{y}, where x and y are positive integers), and the second liner layer includes a silicon oxynitride layer (SiOₓN_{y}, where x and y are positive integers).

20. The semiconductor device of claim 16, further comprising:
a gate electrode crossing the active region in a first direction and extending to the trench isolation layer above the semiconductor substrate,
a gate insulating layer below a gate electrode on the semiconductor substrate, and
a source region and a drain region which are separated from each other by the gate electrode in a second direction perpendicular to the first direction on the semiconductor substrate,
the multi-liner layer being adjacent to the gate electrode and the gate insulating layer in the first direction parallel to the gate electrode and being in an area adjacent to edges of the source and drain regions.

21. A semiconductor device comprising:
a semiconductor substrate;
a trench in the semiconductor substrate; and
a multi-liner layer on at least one inside wall of the trench;
the multi-liner layer being configured to restrict a flow of charges therethrough.

22. The semiconductor device of claim 21, wherein the multi-liner layer includes a first liner layer on the inside wall of the trench and a second liner layer on the first liner layer.

23. The semiconductor device of claim 22, further comprising:
a third liner layer on the second liner layer.

24. The semiconductor device of claim 23, wherein a charge trap density of the second liner layer is higher than a charge trap density of the first liner layer and lower than a charge trap density of the third liner layer.

25. The semiconductor device of claim 23, wherein the first liner layer includes a silicon oxide layer (SiₓO_{y}, where x and y are positive integers), the second liner layer includes a silicon oxynitride layer (SiOₓN_{y}, where x and y are positive integers), and the third liner layer includes a silicon nitride layer (SiₓN_{y}, where x and y are positive integers).

26. The semiconductor device of claim 21, wherein:
the trench is defined by a trench isolation layer; and
the multi-liner layer is on at least one inside wall of the trench isolation layer.
